(19) United States
(12) Patent Application Publication
(10) Pub. No.: US 2006/0237752 A1
(43) Pub. Date: Oct. 26, 2006

(54) Schottky barrier MOSFET device and circuit

(76) Inventors: John M. Larson, Northfield, MN (US); John P. Snyder, Edina, MN (US)

Correspondence Address: DORSEY & WHITNEY LLP;INTELLECTUAL PROPERTY DEPARTMENT, SUITE 1500, 50 SOUTH SIXTH STREET, MINNEAPOLIS, MN, 55402-1498, US

(21) Appl. No.: 11/388,781

(22) Filed: Mar. 24, 2006

Related U.S. Application Data
(60) Provisional application No. 60/666,991, filed on Mar. 31, 2005.

(51) Int. Cl. H01L 29/80

(52) U.S. Cl. 257/260

(57) ABSTRACT

A Schottky barrier integrated circuit is disclosed, the circuit having at least one PMOS device or at least one NMOS device, at least one of the PMOS device or NMOS device having metal source-drain contacts forming Schottky barrier or Schottky-like contacts to the semiconductor substrate. The device provides a lower capacitance between source and gate, which improves device and circuit power and speed performance.

### CROSS-REFERENCE TO RELATED APPLICATION(S)

This application claims the benefit of and priority to U.S. provisional patent application Ser. No. 60/666,991, filed Mar. 31, 2005 which is incorporated by reference herein in its entirety.

### FIELD OF THE INVENTION

The present invention generally relates to the field of semiconductor integrated circuits (ICs). More particularly, the present invention relates to ICs having Schottky barrier Metal-Oxide-Semiconductor-Field-Effect-Transistors (MOSFETs) including at least one Schottky barrier P-type MOSFETs (PMOS) or N-type MOSFETs (NMOS) and/or Schottky barrier complimentary MOSFETs (CMOS).

### BACKGROUND OF THE INVENTION

When scaled to sub-30 nm gate lengths, traditional CMOS technology is approaching fundamental limits, as highlighted by the International Technology Roadmap for Semiconductors (ITRS). Critical technology challenges cited by the ITRS include gate leakage due to extremely thin gate insulators, various deleterious short channel effects, and parasitic resistance/capacitance. Furthermore, shallow doped source/drain junction formation is becoming a necessity but is leading to increasingly complex fabrication processes, requiring precise implant control and tight thermal budgets. Threshold voltage variation, manufacturability and yield issues further hinder implementation of highly scaled doped source/drain junction CMOS technology. Many of these and other CMOS technology challenges are traceable to the doped source/drain architecture and corresponding manufacturing processes. Replacing the doped source/drain MOSFET architecture with a metal source/drain structure offers an elegant solution to a number of scaling challenges, including those listed above.

Although there are numerous compelling reasons to consider metal source/drain Schottky barrier CMOS (SB-CMOS) technology for highly scaled CMOS applications, early fabrication and simulation results were far from optimal. Furthermore, Schottky barrier NMOS engineering challenges impeded the realization of SB-CMOS circuits. However, due to recent progress in simulation, device fabrication and engineering, interest in SB-CMOS technology continues to grow. Based on new measurements, a capacitance mechanism is proposed to explain an unexpectedly high f_{T} performance. This mechanism will also play a role in enhancing the digital logic speed and power performance of SB-CMOS technology.

### BRIEF SUMMARY OF THE INVENTION

In one aspect, the present invention provides an integrated circuit, the integrated circuit comprising: at least one NMOS device or PMOS device; wherein at least one of the NMOS devices or PMOS devices is a Schottky barrier MOS (SB-MOS) device with substantial bulk charge transport.

In another aspect of the present invention, a CMOS circuit is provided. The CMOS circuit comprises at least one Schottky barrier NMOS device; at least one Schottky barrier PMOS device, electrically connected to the at least one Schottky barrier NMOS device; wherein at least one of the Schottky barrier NMOS devices or the Schottky barrier PMOS devices provides substantial bulk transport.

In another aspect of the present invention, a CMOS circuit is provided. The CMOS circuit comprises at least one Schottky barrier NMOS device; at least one Schottky barrier PMOS device, electrically connected to the at least one Schottky barrier NMOS device; wherein at least one of the Schottky barrier NMOS devices or the Schottky barrier PMOS devices provides a capacitance determined by measurements of cutoff frequency f_{T} and transconductance gₘ that is less than an expected capacitance based on physical parameters of the device.

In one embodiment of the invention the Schottky barrier NMOS and Schottky barrier PMOS devices each comprise a semiconductor substrate, a gate electrode on the semiconductor substrate, and a source electrode and a drain electrode on the semiconductor substrate. The source and drain electrodes define a channel region having a channel-length and having mobile charge carriers, wherein at least one of the source electrode and drain electrode forms a Schottky or Schottky-like contact to the substrate.

While multiple embodiments are disclosed, still other embodiments of the present invention will become apparent to those skilled in the art from the following detailed description, which shows and describes illustrative embodiments of the invention. As will be realized, the invention is capable of modifications in various obvious aspects, all without departing from the spirit and scope of the present invention. Accordingly, the drawings and detailed description are to be regarded as illustrative in nature and not restrictive.

### BRIEF DESCRIPTION OF THE DRAWINGS AND TABLES

FIG. 1 illustrates electrical results for 80 nm Schottky barrier PMOS transistors. (a) Drain current versus drain voltage. (b) Drain current and saturation transconductance versus gate voltage. V*_{g} is the applied gate bias increased by +1.1V to account for the N+ poly gate work function difference. V*_{g} is the equivalent gate bias had P+ poly-equivalent gates with minimal poly-depletion been used;

FIG. 2 illustrates electrical results for 60 nm Schottky barrier PMOS transistors. (a) Drain current versus drain voltage. (b) Drain current and saturation transconductance versus gate voltage. V*_{g} is the applied gate bias increased by +1.1V to account for the N+ poly gate work function difference. V*_{g} is the equivalent gate bias had P+ poly-equivalent gates with minimal poly-depletion been used.

FIG. 3 illustrates electrical results for 25 nm Schottky barrier PMOS transistors. (a) Drain current versus drain voltage. (b) Drain current and saturation transconductance versus gate voltage. V*_{g} is the applied gate bias increased by +1.1V to account for the N+ poly gate work function difference. V*_{g} is the equivalent gate bias had P+ poly-equivalent gates with minimal poly-depletion been used.

FIG. 4 illustrates current gain h₂₁ and f_{T} measurements. The S-parameters were measured from 1 to 110 GHz. Due to signal degradation above approximately 50 GHz, f_{T} was determined by extrapolation of current gain from the measured gain at 40 GHz assuming a 20 dB/decade slope.

FIG. 5 illustrates a comparison of f_{T} performance for Schottky barrier PMOS devices (filled) and conventional PMOS devices having doped source/drains (open). The filled diamond data is at over-drive bias conditions. The shaded circles are SB-PMOS data, where the drain is biased at the base bias condition of V_{d}=1.2V and 1.35V for the 60 nm and 80 nm device respectively. The dashed line provides an approximate power-law curve fit to the PMOS literature f_{T} data trend.

FIG. 6 illustrates comparison of C_{gs} ratio for SB-PMOS devices (filled circles) and literature doped source/drain PMOS (open triangles) and NMOS (open squares).

TABLE 1 illustrates a summary of DC performance of 25 nm, 60 nm and 80 nm Schottky barrier PMOS devices. All devices had a 1.8 nm gate oxide. The ITRS roadmap high performance logic data comes from the 2000 Update (80 nm device), 2002 Edition (60 nm device) and 2004 Update (25 nm device). ITRS entries marked “red” indicate this parameter has no known manufacturable solution. ITRS entries marked “yellow” indicates this parameter has known manufacturable solutions. V*_{g} is the applied gate bias increased by +1.1V to account for the N+ poly gate work function difference. V*_{g} is the equivalent gate bias had P+ poly-equivalent gates with minimal poly-depletion been used.

TABLE 2 illustrates a summary of DC and RF performance for 60 nm and 80 nm gate length Schottky barrier PMOS devices. V*_{g} is the applied gate bias increased by +1.1V to account for the N+ poly gate work function difference. V*_{g} is the equivalent gate bias had P+ poly-equivalent gates with minimal poly-depletion been used.

TABLE 3 illustrates a comparison of the expected gate-to-source capacitance (C_{gs,exp}) with the estimated C_{gs} based on f_{T} and gₘ measurements (C_{gs, fT)}. C_{gs,exp} is calculated based on the physical parameters for each device using equation 3.

### DETAILED DESCRIPTION

Device Fabrication and Measurement

Bulk silicon Schottky barrier PMOS (SB-PMOS) devices were fabricated using a modified version of a simple four-mask process. A blanket As implant to the active area was modified to have a dose of either 1×10¹³ cm⁻² (“full implant”) or 5×10¹² cm⁻² (“half-dose implant”). 25 nm, 60 nm and 80 nm gate length devices are characterized. An n-type gate rather than p-type gate for the PMOS devices was used, resulting in a 1.1 V threshold voltage shift. Furthermore, a relatively thick gate oxide having an EOT of 1.8 nm was used, whereas the ITRS recommends for high performance logic a physical EOT of approximately 0.9, 1.2 nm and 1.4 nm for 25, 60 nm and 80 nm gate length devices, respectively.

DC I-V measurements were performed using an Agilent 4155C Parameter Analyzer while scattering parameters were measured with on-wafer probes up to 110 GHz using an HP 8510C Network Analyser linked to a Cascade Microtech Probe Station incorporating an Agilent E7352L/R 110 GHz test head. The ground-signal-ground transistor test structure comprised two fingers, each having a width of 2 μm. Standard RF calibration procedures were used to de-embed probe-to-pad parasitic capacitance. DC I-V measurements performed before and after the scattering parameter measurements ensured device integrity.

Results and Discussion

DC Results

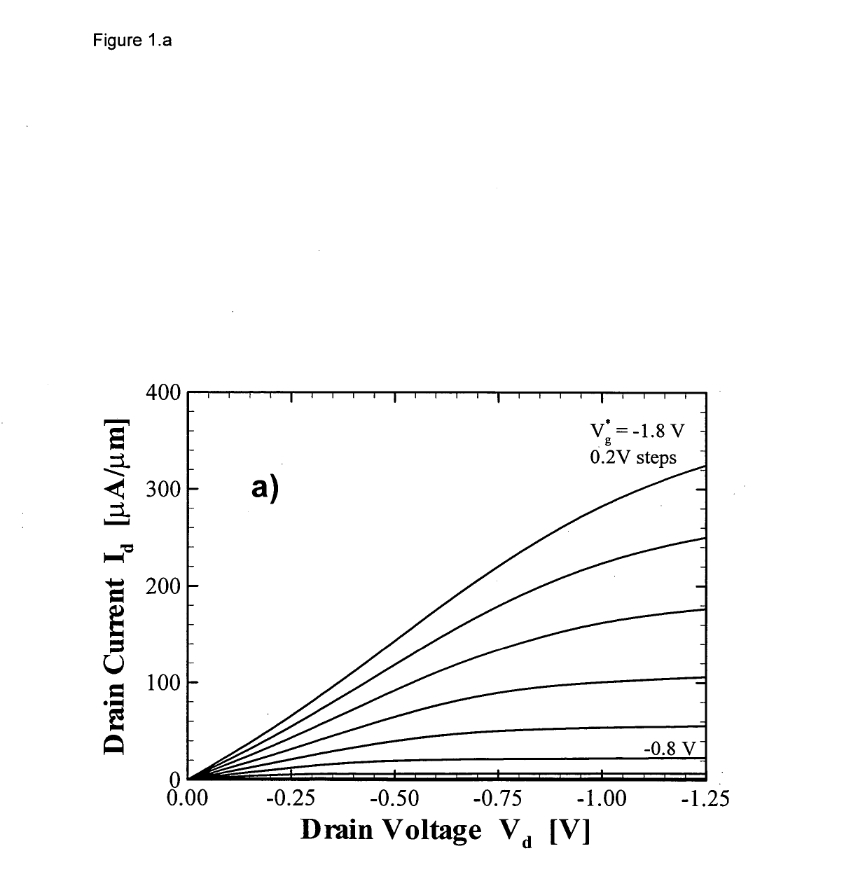

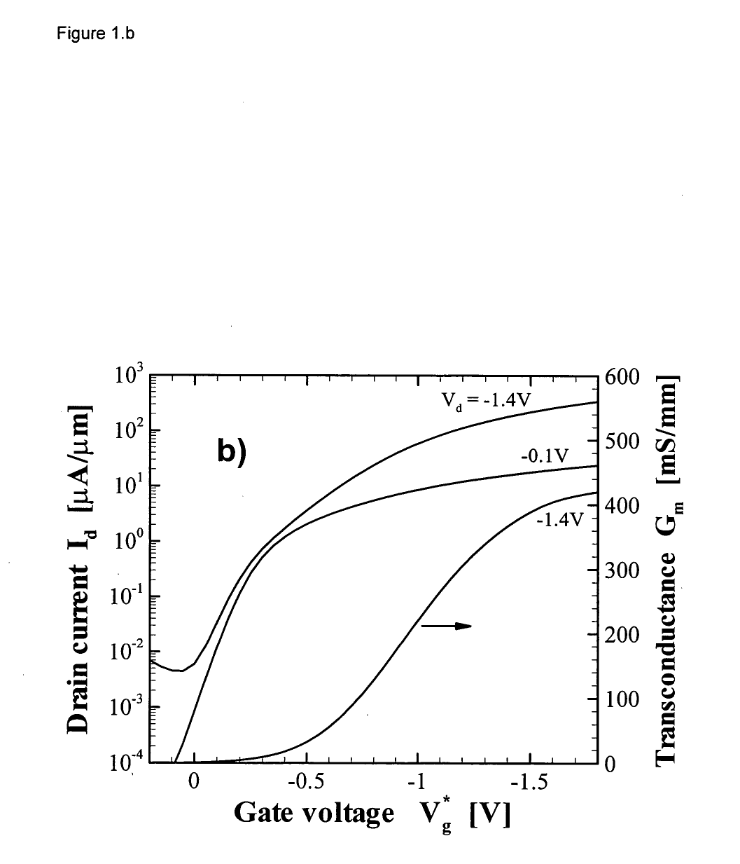

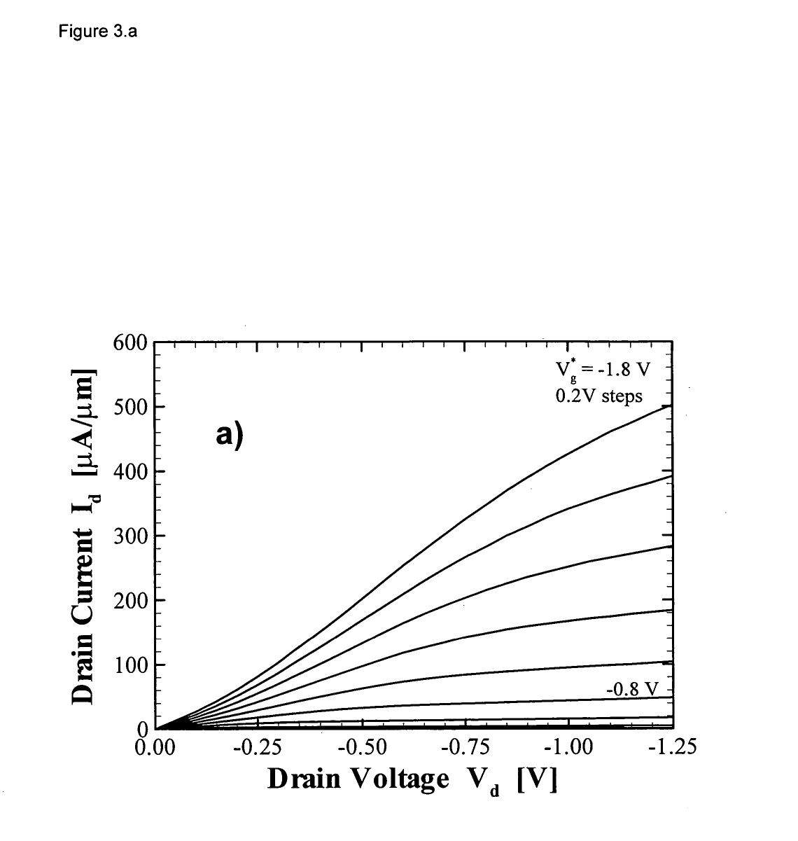

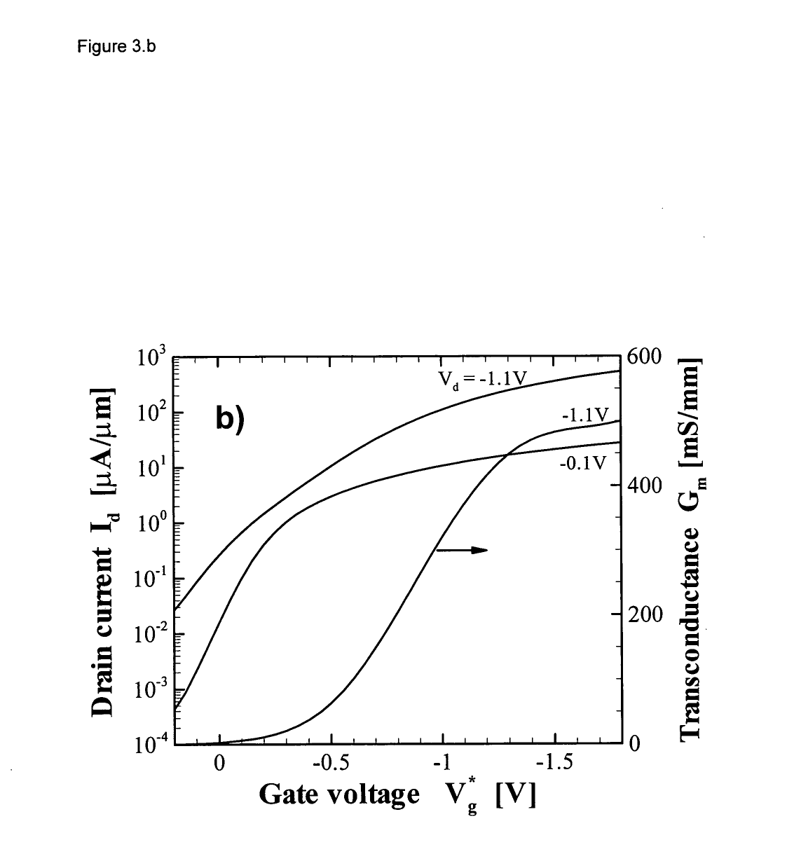

FIG. 1-FIG. 3 show 80 nm, 60 nm and 25 nm transistor I-V curves. These devices all received the full implant. As noted above, the n-type poly gates introduce a −1.1V threshold voltage shift. In FIG. 1- FIG. 3, V*_{g} is reported, which is the applied gate bias V*_{g} shifted by +1.1V to account for using n-type poly gates. V*_{g} in the on-state was set to provide an appropriate electric field in the oxide (E_{OX}) for each gate length device. E_{OX} was calculated using detailed MOS capacitor software that accounted for the N+ poly gate, the relatively thick gate oxide of 1.8 nm, poly depletion and inversion layer quantization effects. For example, although the applied voltage V*_{g} was −2.9V for the 25 nm devices, this is equivalent to V*_{g}=−1.8V had P+ poly gates been used under the condition that minimal poly-depletion is present. This is possible for heavily doped poly or when using metal gates having work functions similar to P+ poly. Further, V*_{g} of −1.8V applied on a 1.8 nm gate oxide is effectively the same as applying −1.1V to a metal gate on a 0.9 nm EOT gate insulator, the metal gate having a work function similar to P+ poly. A summary of the bias conditions and E_{OX} is provided for each device in Table 1.

Table 1 summarizes the DC results and includes for reference the ITRS specifications for devices of similar geometries. The 80 nm device has a drive current of 300 μA/μm, off-state current of 6 nA/μm, resulting in an on-off ratio of 50,000. The subthreshold swing is 91 mV/dec and DIBL is 25 mV/V. Transconductance (Gₘ) is 420 mS/mm. ITRS specifications for 80 nm devices from 2000 roadmap were 350 μA/μm and 13 nA/μm on- and off-current respectively. Although the process technology used in the present invention was tailored for fabricating sub-30 nm transistors, this 80 nm device data nearly meets the high performance logic performance requirements as suggested by the ITRS, exceeding the off-state and on/off current ratio requirements while nearly meeting the on-state requirements. This is accomplished without using SOI substrates, complicated interfacial layer structures, or optimization experiments.

Referencing FIG. 1, for low V_{d}, the drain current is suppressed due to the reverse-biased Schottky barrier contact on the source-side, which provides a finite contact resistance to the channel and results in a sub-linear I-V characteristic. This low V_{d} sub-linear characteristic may play a role in determining the frequency response of SB-CMOS technology. However, as will be discussed below, the frequency response is also determined by the capacitance of the device, and the capacitance of metal source/drain devices has received little consideration to date.

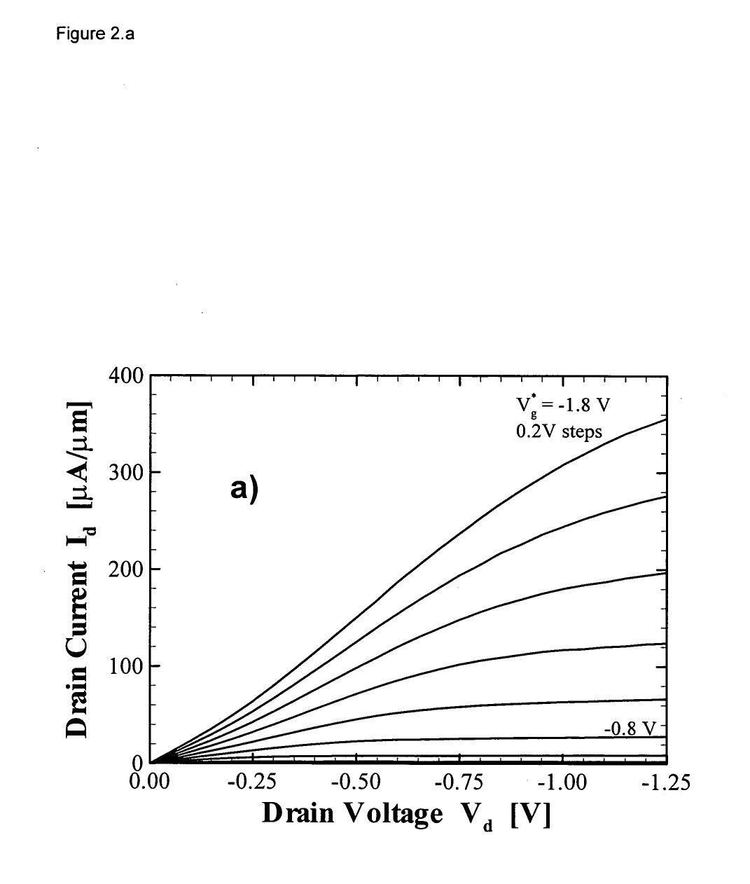

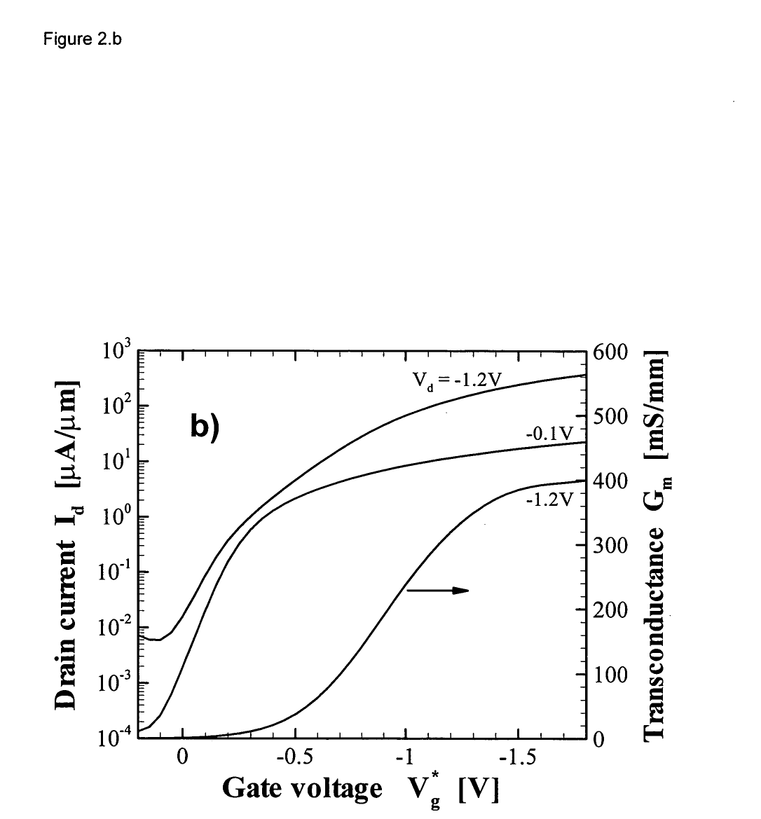

Shorter gate length devices of 60 nm and 25 nm were also measured, as shown in FIG. 2 and FIG. 3 respectively, and summarized in Table 1. As with the 80 nm device, the 60 nm device meets the off-state and on/off current ratio requirements of the 2002 ITRS for high performance logic, and nearly meets the drive current requirements. The 25 nm device nearly meets the 2004 ITRS high performance logic recommendations for 25 nm devices and is competitive with the state-of-the-art.

RF Results

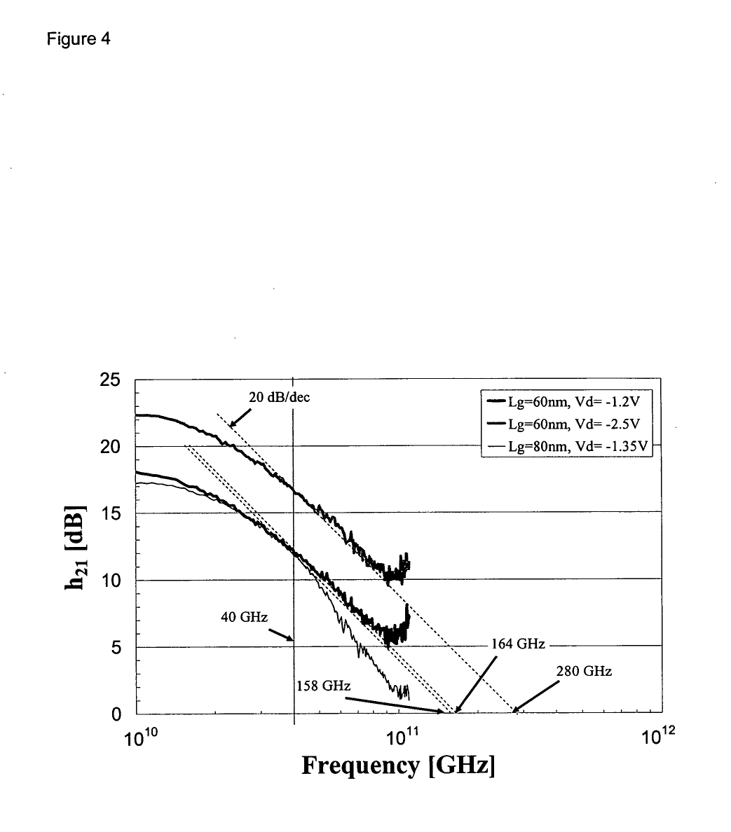

While the devices measured for DC electrical characteristics received the full implant, the RF measurements were performed on devices having the half dose implant. FIG. 4 shows the current gain (h₂₁) plotted as a function of frequency, from which f_{T} is extracted for 60 nm and 80 nm gate length devices. For all three cases shown in FIG. 4, the current gain becomes noisy above 50 GHz and the slope of the curve tends to rise or fall below the expected 20 dB/decade slope. The change in slope at 50 GHz can be attributed to limitations in the standard de-embedding procedure and the onset of electromagnetic coupling between input and output pads. For this reason, we chose to extrapolate the current gain at 20 dB/decade from the gain measured at 40 GHz to estimate f_{T}. Because the gates were not silicided, a high gate resistance resulted in poor f_{MAX} performance and so f_{MAX} data are not presented. We also attempted to measure f_{T} on 25 nm devices, but the h₂₁ data was significantly noisier with lower quality, so this data will not be reported.

Table 2 summarizes the measured f_{T} results together with on-current (Iₒₙ), off-current (I_{off}) and saturation transconductance (gₘ) data for the measured devices shown in FIG. 4. Transconductance and f_{T} were measured at V_{d} shown in Table 2 and at the peak gₘ, which occurred at the maximum V_{g}. The bias conditions for the 60 nm and 80 nm devices are similar to those used for DC testing. In addition, the 60 nm device was tested using a high drain voltage of 2.5V. The gate bias V*_{g} was chosen using the same approach as used for the DC measurements.

Due to the lighter implant, these devices provide improved on-current of 423 μA/μm and 452 μA/μm for the 60 nm and 80 nm devices respectively at the expense of higher off-state current. Over-driving the 60 nm device further increases the on-current to 614 μA/μm. The transconductance is 528 mS/mm and 548 mS/mm for the 60 nm and 80 nm devices respectively. For the 60 nm device, f_{T} is 164 GHz and 280 GHz at the standard and over-drive bias conditions respectively, while f_{T} is 158 GHz for the 80 nm device at the standard bias condition.

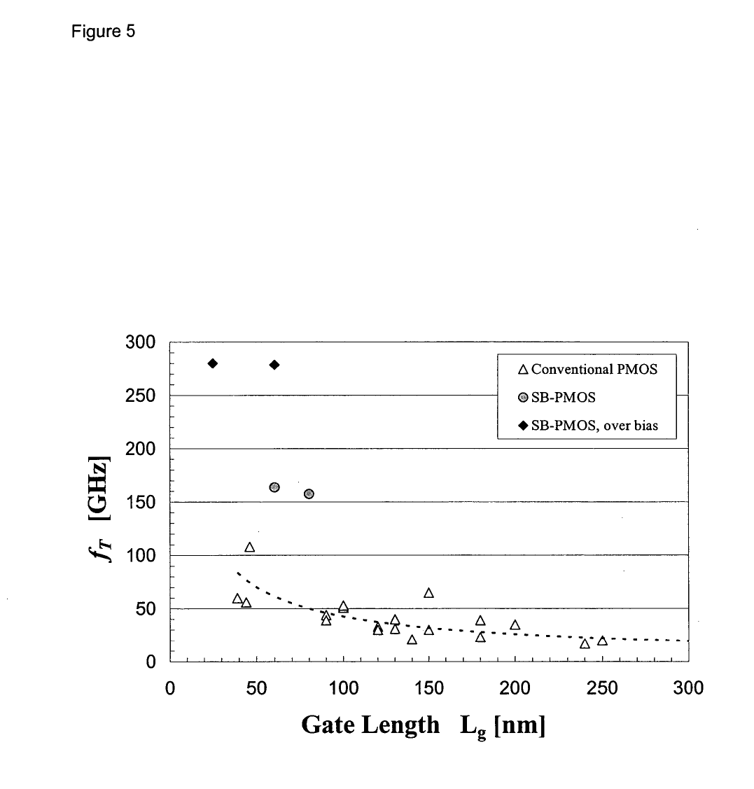

FIG. 5 provides a comparison of theft measurements of the present invention and the reports from the literature for measured silicon-based PMOS f_{T} data for gate lengths ranging from 40 nm to 200 nm. The measured PMOS f_{T} for conventional doped source/drain devices in the literature is generally between 20 and 60 GHz as gate length scaled to 40 nm. The dashed line in FIG. 5 is the projected PMOS f_{T} performance for conventional doped source/drain devices based on the literature data trends.

Unlike the SB-PMOS f_{T} data reported by us previously in which the 25 nm devices were significantly over-driven, non-over-driven bias conditions were used in the present invention. As shown in FIG. 5, for devices of 60 and 80 nm gate lengths, the resulting f_{T} is a factor of 2.7 and 3.2 greater respectively than the expected f_{T} from the trend of the literature data. When over-driven, f_{T} increases by nearly another factor of two and the ratio of 60 nm SB-PMOS device f_{T} to conventional f_{T} increases from 2.7 to 4.5.

In order to explain the significantly improved f_{T} performance of the SB-PMOS devices, we considered the key parameters that determine f_{T}, including transconductance (gₘ) and gate-to-source capacitance (C_{gs}):

$${f}_{T} \approx \frac{{g}_{m}}{2 π {C}_{gs}} . \qquad ( 1 )$$

Although gₘ for these devices is good as shown in Table 2, it is not sufficiently high to explain the observed factor of 2-4 enhancement in f_{T}. For this reason, we examined C_{gs}, comparing C_{gs} based on the f_{T} and gₘ measurements (C_{gs,fT}):

$${C}_{gs , fT} = \frac{{g}_{m}}{2 π {f}_{T}} \qquad ( 2 )$$

with an expected C_{gs} based on the physical parameters of the fabricated devices (C_{gs,exp}):
C_{gs,exp}=C_{gs,ox}+C_{gs,o}+C_{gs,f}. (3)
The gate-to-source capacitance originating from the channel region (C_{gs,ox}) is:

$${C}_{gs , ox} = \frac{2}{3} \frac{{ɛ}_{{SiO}_{2} {L}_{g}}}{{EOT}_{inv}} \qquad ( 4 )$$

and C_{f} is the parasitic fringing capacitance:

$${C}_{gs , f} = \frac{2 {ɛ}_{{SiO}_{2}}}{π} [ ln ( 1 + \frac{{T}_{poly}}{{T}_{ox}} ) + ln \frac{π}{2} + 0.308 ] . \qquad ( 5 )$$

T_{poly} is the thickness of the poly gate, L_{g} is the gate length, EOTᵢₙᵥ is the effective oxide thickness in inversion and accounts for the oxide thickness (Tₒₓ), and poly depletion and inversion layer quantization effects. The gate-to-source overlap capacitance is C_{gs,o}. The component of capacitance originating from the channel C_{gs,ox} is assumed to be ⅔ of the total gate capacitance when the device is operated in the on-state, which is standard practice in the industry. Therefore, with knowledge of the device physical parameters and measurements of f_{T} and gₘ, one can compare C_{gs,exp} with C_{gs,fT}. The ratio C_{gs,fT}/C_{gs,exp} should be approximately one for any combination of L_{g} and EOT.

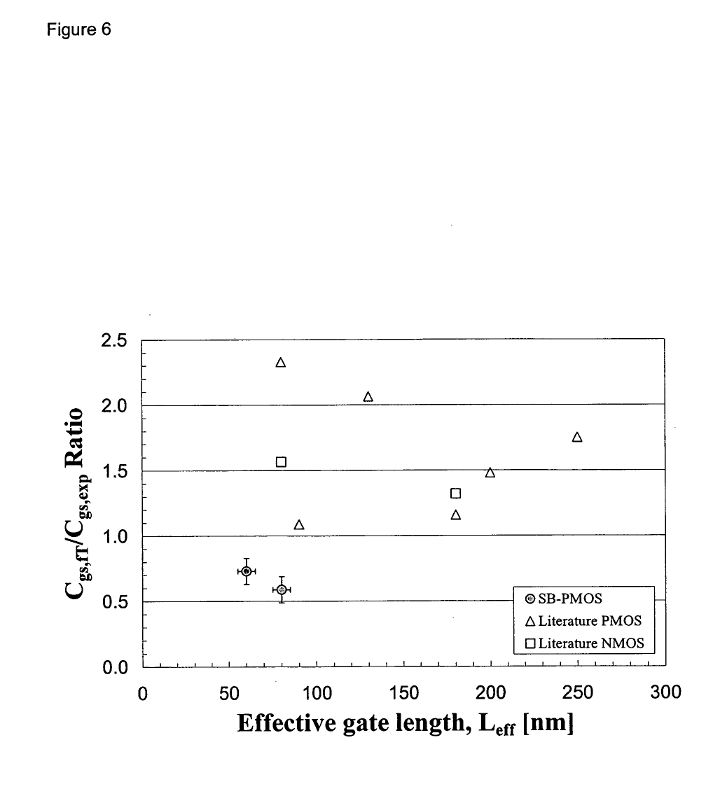

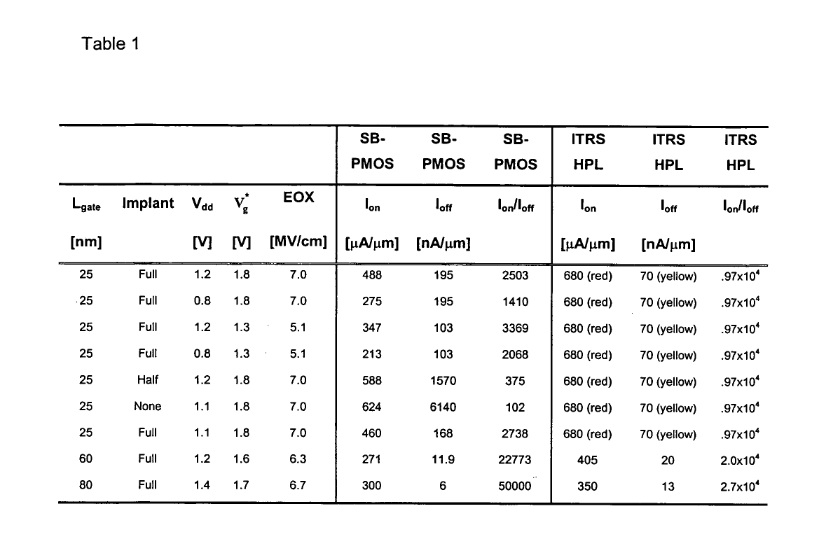

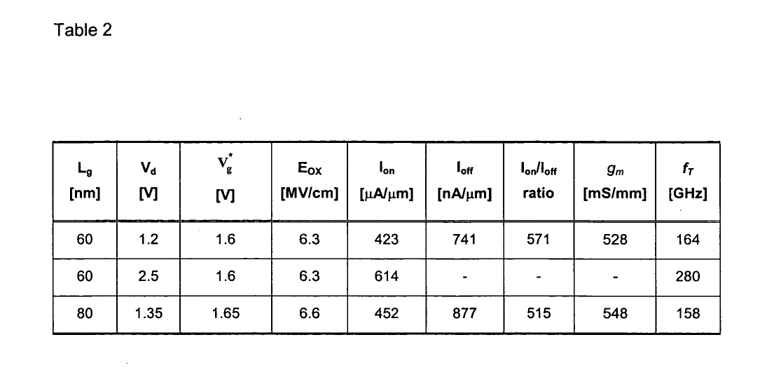

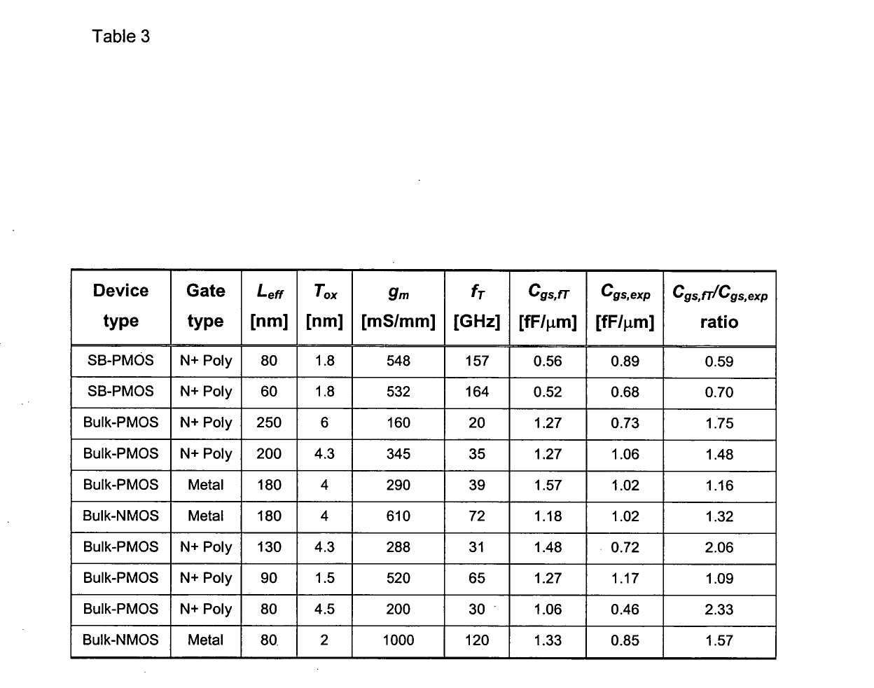

Table 3 provides data for calculating the C_{gs} ratio C_{gs,fT}/C_{gs,exp} for a variety of examples from known literature, and for the devices reported in the present invention. FIG. 6 plots the C_{gs} ratio data as a function of gate length (L_{g}). In Table 3, all of the PMOS devices have either metal gates or N+ doped poly gates, which means poly depletion effects can be neglected. For the NMOS devices, only metal gate devices were selected, again so that poly depletion effects can be neglected. The portion of oxide electrical thickness adjustment due to inversion layer quantization effects was assumed to be a constant for all devices at 0.4 nm. Because poly depletion effects were negligible, EOTᵢₙᵥ was therefore estimated to be Tₒₓ plus a constant of 0.4 nm. For the SB-PMOS devices, C_{gs,f} was calculated using Eq. 5 and C_{gs,o} was assumed to be zero since high resolution cross-sectional TEM analysis showed no gate-to-source overlap. For example, for the 80 nm SB-PMOS device, having a 115 nm-thick poly gate, C_{gs,ox}=0.837 fF/μm, C_{gs,f}=0.108 fF/μm and C_{gs,o}=0.0 fF/μm for a total expected gate-to-source capacitance of 0.945 fF/μm. For the literature devices, a net C_{gs,f}+C_{gs,o} value of 0.08 fF/μm was assumed, based on ITRS specifications. Typically, for the literature devices, the net fringe plus overlap capacitance was approximately 10-30% of the total expected capacitance. A 50% error in the assumed value of C_{gs,f}+C_{gs,o} results in a 5% error in the calculation of the C_{gs} ratio C_{gs,fT}/C_{gs,exp}. Error bars are provided in FIG. 6 for the SB-PMOS data based on uncertainties in the actual device physical parameters.

As shown in Table 3 and FIG. 6, the C_{gs} ratio for SB-PMOS devices is less than 1.0 (0.59 and 0.73), indicating that the measured C_{gs,fT} is less than the capacitance predicted by the simple model in equation 3. In contrast, the conventional devices from the literature all provide a C_{gs} ratio greater than 1.0 (1.09 to 2.06), indicating the measured C_{gs,fT} is greater then the expected capacitance. Further, although it is difficult to compare the absolute magnitudes of the capacitances, the 80 nm SB-PMOS device is comparable to the 90 nm Bulk PMOS device having a 1.5 nm Tₒₓ. In this case, the magnitude of the estimated capacitance for the SB-PMOS device is 0.89 fF/μm while for the Bulk PMOS device it is 1.17 fF/μm, or a factor of 1.3 higher due to the larger L_{g} and smaller Tₒₓ. The measured C_{gs,fT} for the SB-PMOS device is 0.56 fF/μm while for the bulk PMOS device is 1.27 fF/μm, a factor of 2.3 higher. In this instance where direct comparison of capacitance can be made, the capacitance determined from the f_{T} and gₘ measurements is significantly lower for the SB-PMOS device than that of the bulk PMOS device.

Regarding the comparison of the capacitance ratio, it is apparent that the simple model described by equations 3-5 over-estimates the SB-PMOS capacitance. Referencing equations 3-5, the parameter of greatest uncertainty is EOTᵢₙᵥ, which was assumed to be Tₒₓ plus a constant of 0.4 nm due to inversion layer quantization effects. High resolution cross-section TEM analysis was used to estimate Tₒₓ, so the error in Tₒₓ is relatively small. However, EOTᵢₙᵥ may not be simply Tₒₓ plus the constant 0.4 nm for SB-MOS devices. Further simulation, fabrication and electrical testing will be required to explain enhanced f_{T} performance.

Finally, it is worth noting that reduced device capacitance plays a role both for f_{T}, as well as for other performance metrics such as gate delay (τ) and energy (E), which both scale linearly with gate capacitance:

$$\begin{matrix}τ• \frac{{C}_{g} {V}_{dd}}{{I}_{d}} & ( 6 ) \\ E • {C}_{g} {V}^{2} . & ( 7 )\end{matrix}$$

As noted previously, SB-MOS devices exhibit a sub-linear turn-on characteristic for low V_{d}. However, while I_{d} is reduced, according to the measurements above, C_{g} may simultaneously be reduced, which may more than compensate for the reduced current in the low V_{d} regime. Further, for higher V_{d}'s, where the current drive of SB-PMOS devices is good, the results of the present invention suggest C_{g} will continue to be significantly lower than conventional doped source/drain devices, while the currents will be similar. It is impossible to predict the net effect of this reduced capacitance on the overall frequency response of SB-CMOS technology in digital circuits. It is apparent that some prior assumptions about the ultimate performance of SB-CMOS technology may have been premature. Furthermore, reduced capacitance may relax requirements for drive current and NMOS engineering, making high performance SB-CMOS technology more achievable.
Conclusion

New 25 nm, 60 nm and 80 nm DC transistor curve measurements are reported for SB-PMOS. The 60 nm and 80 nm devices provide performance nearly commensurate with prior ITRS specifications for high performance logic, while the 25 nm devices provide competitive performance with the sub-35 nm state-of-the-art. New f_{T} measurements for high speed SB-PMOS 60 nm (164 GHz) and 80 nm (158 GHz) devices were also presented. By using a metal source/drain architecture, f_{T} performance is enhanced by a factor of 2-3 at equivalent gate lengths and using standard roadmap bias conditions. In view of gₘ data and estimates for the gate-to-source capacitance C_{gs}, the metal source/drain SB-MOS device architecture provides a significantly reduced C_{gs}, compared to doped source/drain MOSFET technology, which results in enhanced f_{T} performance. One possible mechanism causing reduced C_{gs} is a more disperse charge distribution in the channel region, although additional simulation and device measurements will be required to validate this proposed theory. Finally, reduced gate capacitance provides speed and power advantages for both RF mixed signal and digital logic applications, and will help enable demonstration of high performance SB-CMOS technology.

The present invention teaches an integrated circuit having at least one SB-PMOS device or at least one SB-NMOS device having substantial bulk charge transport, which thereby counteracts the effects provided by the sub-linear turn-on characteristic, and thereby provides improved IC performance. The present invention is particularly suitable for use in situations where short channel length MOSFETs are to be fabricated, especially in the range of channel lengths less than 500 nm. However, nothing in the teachings of the present invention limits application of the teachings of the present invention to these short channel length devices.

Although the present invention has been described with reference to preferred embodiments, persons skilled in the art will recognize that changes may be made in form and detail without departing from the spirit and scope of the invention. The application of the present invention applies to any use of metal source drain technology, whether it employs SOI substrate, strained Silicon substrate, SiGe substrate, FinFET technology, high K gate insulators, and metal gates. This list is not limitive. Any device for regulating the flow of electric current that employs metal source-drain contacts used in an IC will have the benefits taught herein.

We claim:

1. An integrated circuit, the integrated circuit comprising:
at least one NMOS device or PMOS device;
wherein at least one of the NMOS devices or PMOS devices is a Schottky barrier MOS device with C_{gs,fT} less than C_{gs,exp}.

2. The integrated circuit of claim 1 wherein at least one of the NMOS device and PMOS device exhibits C_{g,fT} of less than or equal to 75% of C_{gs,exp}.

3. The integrated circuit of claim 1 wherein at least one of the NMOS device and PMOS device exhibit transconductance of at least 90% of the maximum transconductance when gate voltage V_{g} is equal to supply voltage, V_{dd}.

4. The integrated circuit of claim 1 wherein at least one of the NMOS device and PMOS device is a Schottky barrier device comprising:
a semiconductor substrate;
a gate electrode on the semiconductor substrate;
a source electrode and a drain electrode on the semiconductor substrate defining a channel region having a channel-length and having mobile charge carriers, wherein at least one of the source electrode and drain electrode forms a Schottky or Schottky-like contact to the substrate.

5. The integrated circuit of claim 4 wherein the semiconductor substrate is comprised of silicon, strained silicon, silicon on insulator, silicon germanium, gallium arsenide, or indium phosphide.

6. The integrated circuit of claim 4 wherein the source electrode and the drain electrode of the Schottky barrier PMOS device are formed of any one or combination of Platinum Silicide, Palladium Silicide or Iridium Silicide.

7. The integrated circuit of claim 4 wherein the source electrode and the drain electrode of the Schottky barrier NMOS device are formed of any one or combination of the rare-earth suicides such Erbium Silicide, Dysprosium Silicide, or Ytterbium Silicide.

8. The integrated circuit of claim 4 wherein at least one of the source and drain electrodes of the Schottky barrier PMOS devices or Schottky barrier NMOS devices forms a Schottky or Schottky-like contact with the semiconductor substrate at least in areas adjacent to the channel.

9. The integrated circuit of claim 4 wherein an entire interface between at least one of the source and the drain electrodes of the Schottky barrier PMOS devices or Schottky barrier NMOS devices and the semiconductor substrate forms a Schottky contact or Schottky-like region with the semiconductor substrate.

10. The integrated circuit of claim 4 wherein the channel contains channel dopants in the semiconductor substrate.

11. The integrated circuit of claim 10 wherein the channel dopant concentration varies in a vertical direction of the semiconductor substrate and is substantially constant in a lateral direction in the semiconductor substrate.

12. The integrated circuit of claim 10 wherein the channel dopant concentration varies in a vertical direction and a lateral direction in the semiconductor substrate.

13. The integrated circuit of claim 10 wherein the channel dopants for the Schottky barrier PMOS device comprises Arsenic, Phosphorous, Antimony or any combination thereof.

14. The integrated circuit of claim 10 wherein the channel dopants for the Schottky barrier NMOS device comprises Boron, Indium, Gallium or any combination thereof.

15. The integrated circuit of claim 4 wherein the gate electrode of the Schottky barrier PMOS devices or Schottky barrier NMOS devices has a length not exceeding 500 nm.

16. The integrated circuit of claim 4 wherein the gate electrode of at least one of the Schottky barrier NMOS or Schottky barrier PMOS devices comprises:
an insulating layer on the semiconductor substrate;
a conducting film on the insulating layer; and
at least one insulating layer on at least one sidewall of the conducting film.

17. The integrated circuit of claim 16 wherein the mobile charge carriers are substantially removed from the interface of the insulating layer and the semiconductor substrate.

18. The integrated circuit of claim 16 wherein the interaction of the mobile charge carriers with the interface of the insulating layer and the semiconductor substrate is substantially reduced.

19. The integrated circuit of claim 16 wherein the Schottky barrier NMOS device has a gate electrode conducting film comprised of phosphorous doped polysilicon.

20. The integrated circuit of claim 16 wherein the Schottky barrier PMOS device has a gate electrode conducting film comprised of boron doped polysilicon.

21. The integrated circuit of claim 16 wherein the Schottky barrier NMOS device has a metal gate electrode conducting film.

22. The integrated circuit of claim 16 wherein the Schottky barrier PMOS device has a metal gate electrode conducting film.

23. The integrated circuit of claim 16 wherein the insulating layer on the semiconductor substrate is silicon dioxide.

24. The integrated circuit of claim 16 wherein the insulating layer on the semiconductor substrate is a high k dielectric formed from a member comprised of nitrided silicon dioxide, silicon nitride, metal oxides, or any combination thereof.

25. The integrated circuit of claim 1, wherein the device further comprises at least one NMOS device or PMOS device having an impurity doped source and drain electrode electrically connected to a Schottky barrier NMOS or Schottky barrier PMOS device.

26. A CMOS circuit, the CMOS circuit, comprising:
at least one Schottky barrier NMOS device;
at least one Schottky barrier PMOS device, electrically connected to at least one Schottky barrier NMOS device;
wherein at least one of the NMOS devices or PMOS devices is a Schottky barrier MOS device with C_{gs,fT} less than C_{gs,exp}.

27. The CMOS circuit of claim 26 wherein at least one of the Schottky barrier NMOS device and Schottky barrier PMOS device exhibits C_{g,fT} of less than or equal to 75% of C_{gs,exp}.

28. The CMOS circuit of claim 26 wherein the Schottky barrier NMOS and Schottky barrier PMOS devices each comprises:
a semiconductor substrate;
a gate electrode on the semiconductor substrate;
a source electrode and a drain electrode on the semiconductor substrate defining a channel region having a channel-length and having mobile charge carriers, wherein at least one of the source electrode and drain electrode forms a Schottky or Schottky-like contact to the substrate.

29. The CMOS circuit of claim 28 wherein the semiconductor substrate is comprised of silicon, strained silicon, silicon on insulator, silicon germanium, gallium arsenide, or indium phosphide.

30. The CMOS circuit of claim 28 wherein the source electrode and the drain electrode of the Schottky barrier PMOS device are formed from a member comprised of Platinum Silicide, Palladium Silicide or Iridium Silicide.

31. The CMOS circuit of claim 28 wherein the source electrode and the drain electrode of the Schottky barrier NMOS device are formed of any one or combination of the rare-earth suicides such Erbium Silicide, Dysprosium Silicide, or Ytterbium Silicide.

32. The CMOS circuit of claim 28 wherein at least one of the source and drain electrodes of the Schottky barrier PMOS devices or Schottky barrier NMOS devices forms a Schottky or Schottky-like contact with the semiconductor substrate at least in areas adjacent to the channel.

33. The CMOS circuit of claim 28 wherein an entire interface between at least one of the source and the drain electrodes of the Schottky barrier PMOS devices or Schottky barrier NMOS devices and the semiconductor substrate forms a Schottky contact or Schottky-like region with the semiconductor substrate.

34. The CMOS circuit of claim 28 wherein the channel contains channel dopants in the semiconductor substrate.

35. The CMOS circuit of claim 34 wherein the channel dopant concentration varies in a vertical direction of the semiconductor substrate and is substantially constant in a lateral direction in the semiconductor substrate.

36. The CMOS circuit of claim 34 wherein the channel dopant concentration varies in a vertical direction and a lateral direction in the semiconductor substrate.

37. The CMOS circuit of claim 34 wherein the channel dopants for the Schottky barrier PMOS device comprises Arsenic, Phosphorous, Antimony or any combination thereof.

38. The CMOS circuit of claim 34 wherein the channel dopants for the Schottky barrier NMOS device comprises Boron, Indium, Gallium or any combination thereof.

39. The CMOS circuit of claim 28 wherein the gate electrode of the Schottky barrier PMOS devices or Schottky barrier NMOS devices has a length not exceeding 500 nm.

40. The CMOS circuit of claim 28 wherein the gate electrode of at least one of the Schottky barrier NMOS or Schottky barrier PMOS devices comprises:
an insulating layer on the semiconductor substrate;
a conducting film on the insulating layer; and
at least one insulating layer on at least one sidewall of the conducting film.

41. The CMOS circuit of claim 28 wherein the mobile charge carriers are substantially removed from the interface of the insulating layer and the semiconductor substrate.

42. The CMOS circuit of claim 28 wherein the interaction of the mobile charge carriers with the interface of the insulating layer and the semiconductor substrate is substantially reduced.

43. The CMOS circuit of claim 40 wherein the Schottky barrier NMOS device has a gate electrode conducting film comprised of phosphorous doped polysilicon.

44. The CMOS circuit of claim 40 wherein the Schottky barrier PMOS device has a gate electrode conducting film comprised of boron doped polysilicon.

45. The CMOS circuit of claim 40 wherein the Schottky barrier NMOS device has a metal gate electrode conducting film.

46. The CMOS circuit of claim 40 wherein the Schottky barrier PMOS device has a metal gate electrode conducting film.

47. The CMOS circuit of claim 40 wherein the insulating layer on the semiconductor substrate is silicon dioxide.

48. The CMOS circuit of claim 40 wherein the insulating layer on the semiconductor substrate is a high k dielectric formed from a member comprised of nitrided silicon dioxide, silicon nitride, metal oxides, or any combination thereof.

49. The CMOS circuit of claim 28, wherein the device further comprises at least one NMOS device or PMOS device having an impurity doped source and drain electrode electrically connected to the Schottky barrier NMOS or Schottky barrier PMOS devices.
